(19) United States
(12) Patent Application Publication
(10) Pub. No.: US 2006/0067102 A1
(43) Pub. Date: Mar. 30, 2006

(54) Non-volatile logic circuit and system LSI having the same

(75) Inventors: Takayoshi Yamada, Osaka (JP); Yoshihisa Kato, Otsu-shi (JP)

Correspondence Address: GREENBLUM & BERNSTEIN, P.L.C., 1950 ROLAND CLARKE PLACE, RESTON, VA, 20191, US

(73) Assignee: Matsushita Electric industrial Co., Ltd., Osaka (JP)

(21) Appl. No.: 11/234,295

(22) Filed: Sep. 26, 2005

(30) Foreign Application Priority Data
Sep. 28, 2004 (JP) 2004-282216

(51) Int. Cl. G11C 11/22

(52) U.S. Cl. 365/145

(57) ABSTRACT

A non-volatile logic circuit according to the present invention is comprised of: a logic circuit block; and an input/output unit operable to input and output data between the logic circuit block and the input/output unit and between a data bus and the input/output unit, wherein the input/output unit has a non-volatile data holding circuit which holds the data. Furthermore, a system large-scale integration (LSI) according to the present invention is comprised of a plurality of non-volatile logic circuits which are connected with one another via a data bus.

### BACKGROUND OF THE INVENTION

(1) Field of the Invention

The present invention relates to a logic circuit which has non-volatile memory circuits, and more especially to a logic circuit which has non-volatile memories using ferroelectric capacitors and a system LSI having the same.

(2) Description of the Related Art

In recent years, a system LSI which is embedded with signal processing circuits, such as a microcomputer and a digital signal processor (DSP), as intellectual property (IP) cores, has been developed. A plurality of functions have been integrated on a single semiconductor chip in order to downsize an area of the chip and reduce a manufacturing cost. Moreover, a system using a programmable logic array device (PLD), in which functions are set by software, has been widely used in order to easily shorten of a development period of a logic circuit, to change the logic circuit after shipping a product, and to achieve other effects. For these system LSIs, however, it is necessary to initialize each logic circuit block when the systems are powered on. It is also necessary to manage how the logic circuit blocks are connected on the systems.

Japanese Patent Laid-Open No. 2001-352036 publication discloses one example of the initialization of the logic circuit blocks in such a system LSI in which the logic circuit blocks are combined. This document describes the following structure as a method for initializing the logic circuit blocks.

FIG. 1 is a block diagram of a device which includes a semiconductor integrated circuit as a system LSI, as described in the above Japanese Patent Laid-Open No. 2001-352036 publication. The device is comprised of: a memory 6 which stores data for initializing the semiconductor integrated circuit 1; and a control device 5 which sets data for initialization into internal registers 2a to 2d in the semiconductor integrated circuit 1 via a scan path 3. By using the scan path which is used to check the semiconductor integrated circuit 1, the data for initialization is sent to the internal registers, thereby initializing the semiconductor integrated circuit 1.

In the system LSI in the related art, configuration data for each logic circuit block (the semiconductor integrated circuit 1 in FIG. 1) is stored in a programmable ROM (the memory 6 in FIG. 1), such as a EEPROM, which is formed on another chip.

### SUMMARY OF THE INVENTION

However, in the above structure, it is relatively easy for outside devices and the like to read out data in the programmable ROM. Furthermore, on start-up, it is necessary to sequentially read out data for initialization from a programmable ROM. This has caused problems of low data security, time-consuming initialization, and the like.

Furthermore, when the system LSI is powered off, data during operations is lost, and when the system LSI is again powered on, the system needs to start in initialized state. In order to restore the conditions of the system LSI prior to the power-off, it is necessary, on the power-off, to previously store data of each logic circuit block in the system LSI into a non-volatile memory, such as a programmable ROM, then the system LSI is powered off, and when the system LSI is again powered on, the data is read out again.

In view of the above problems, it is an object of the present invention to provide a logic circuit block which enables to perform initialization at a high speed, and a logic circuit block which enables to restore, on start-up, the conditions of the logic circuit block prior to power-off.

In order to achieve the above object, a non-volatile logic circuit according to the present invention is comprised of: a logic circuit block; and an input/output unit operable to input and output data between the logic circuit block and a data bus, wherein the input/output unit has a non-volatile data holding circuit which holds the data.

According to the non-volatile logic circuit of the present invention, an interface which is the input/output unit of the logic circuit block has a non-volatile data holding circuit, so that it is possible to initialize the logic circuit block at a high speed. Furthermore, data in the input/output unit is stored into the non-volatile data holding circuit on power-off, so that it is possible to restore, immediately after start-up, data which has been existed prior to the power-off.

The non-volatile data holding circuit is preferable to have a ferroelectric capacitor.

Thereby, it is possible to easily form the non-volatile data holding circuit.

Furthermore, the logic circuit block is preferably a reconfigurable circuit which is programmed according to configuration data, and preferably has a ferroelectric capacitor for storing the configuration data.

Thereby, input/output data is stored into the non-volatile data holding circuit having the ferroelectric capacitor, and configuration data for the reconfigurable logic circuit block is stored into the ferroelectric capacitor, so that it is possible to form a memory for storing the configuration data and resume data (input/output data) by using single-memory forming processing.

Still further, the non-volatile logic circuit further is able to have a ferroelectric memory core.

Thereby, memory functions can be unified into the ferroelectric memory, so that it is possible to simplify the memory forming processing.

Still further, the ferroelectric memory core is preferably operable to store data for initialization of the logic circuit block.

Thereby, by storing data for initialization of a plurality of other logic circuit blocks, into the ferroelectric memory core, it is possible to execute the plurality of logic circuit blocks at the same time, so that a time period required for the initialization can be shortened.

Still further, the non-volatile data holding circuit is preferably further operable to hold configuration data for the logic circuit block.

Thereby, the time period required for the initialization can be shortened.

Moreover, in order to achieve the above object, a system large-scale integration (LSI) according to the present invention is comprised of a plurality of non-volatile logic circuits which are connected to a data bus, wherein the non-volatile logic circuit has: a logic circuit block; and an input/output unit operable to input and output data between the logic circuit block and a data bus, wherein the input/output unit has a non-volatile data holding circuit which holds the data.

As is obvious from the above description, it is possible for the non-volatile logic circuit and the system LSI having the same according to the present invention to initialize the logic circuit block at a high speed. It is also possible to restore, immediately after start-up, data which has existed in the logic circuit block prior to power-off.

### FURTHER INFORMATION ABOUT TECHNICAL BACKGROUND TO THIS APPLICATION

The disclosure of Japanese Patent Application No. 2004-282216 filed on Sep. 28, 2004 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a diagram showing one example of a conventional logic circuit;

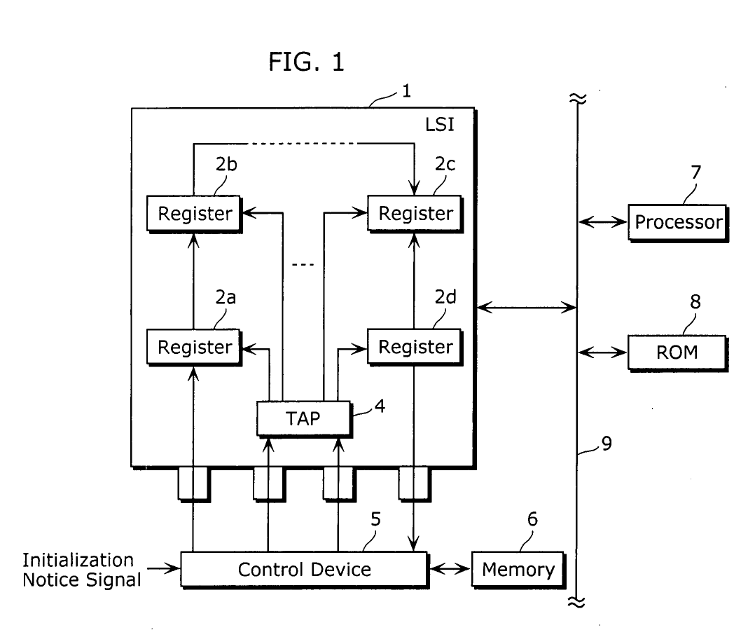

FIG. 2 is a block diagram of a system LSI according to an embodiment of the present invention;

FIG. 3 shows one example of a circuit when a non-volatile data holding circuit in a non-volatile I/F is formed by a ferroelectric memory;

FIG. 4 is a flowchart showing processing performed by a non-volatile logic circuit when the system LSI is powered on and when the system LSI is powered off;

FIG. 5 is a block diagram of a non-volatile logic circuit according to the first variation;

FIG. 6 is a flowchart showing processing when the system LSI is powered on and when the system LSI is powered off, according to the first variation;

FIG. 7 is a block diagram of a system LSI according to the second variation;

FIG. 8 is a block diagram of a system LSI according to the third variation;

FIG. 9 is a flowchart showing initialization processing when the system LSI is powered on, according to the third variation; and

FIG. 10 is a flowchart showing initialization processing when the conventional system LSI is powered on.

### DESCRIPTION OF THE PREFERRED EMBODIMENT

The following describes one embodiment according to the present invention with reference to the drawings.

### EMBODIMENT

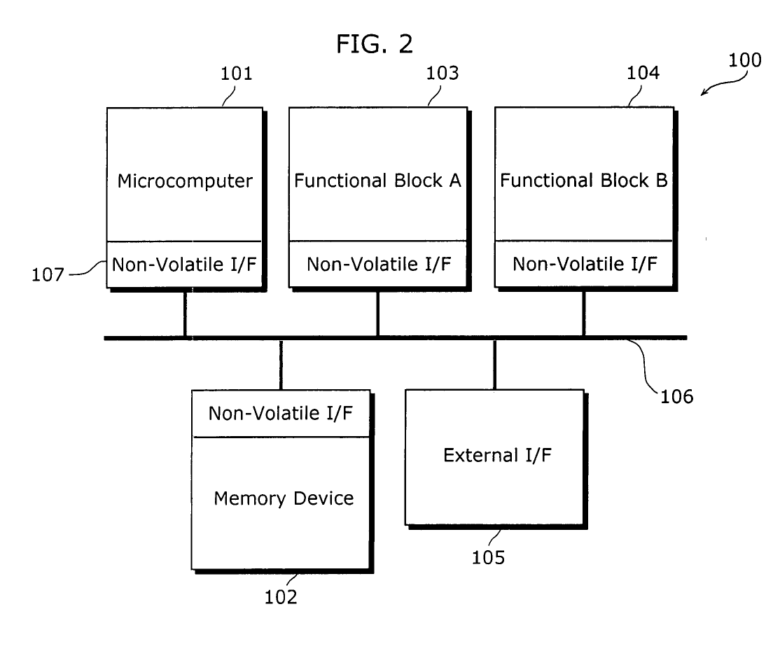

The following describes a non-volatile logic circuit and a system LSI having the same according to one embodiment of the present invention with reference to FIGS. 2 to 10.

FIG. 2 is a block diagram of the system LSI in which non-volatile logic circuits are connected to a data bus, according to the present embodiment.

A system LSI 100 according to the present embodiment is comprised of: a functional block 101 which has a function as a microcomputer; a functional block 102 which has a function as a memory; a functional block A103 which has another function A; a functional block B104 which has still another function B; and a circuit 105 which has a function of inputting and outputting data between the circuit 105 and an external circuit, all of which are connected via a data bus 106. Here, the functional blocks 101 to 104 are non-volatile logic circuits according to the present embodiment, each of which includes: a plurality of logic circuits (logic circuit block) for implementing each function, and an input/output unit (non-volatile I/F) 107 which is connected with the data bus 106. Each non-volatile I/F 107 inputs and outputs data between a plurality of the logic circuits in the functional block and the data bus, and has a non-volatile data holding circuit for holding the data.

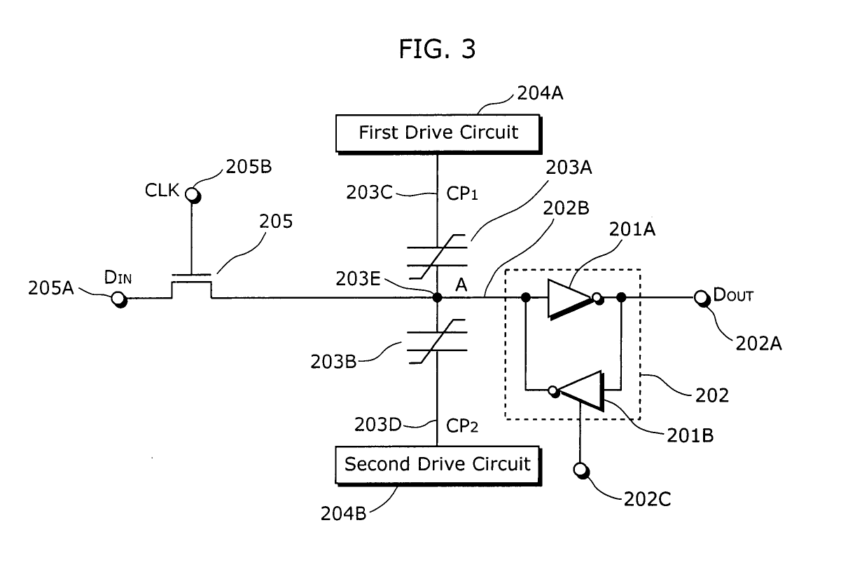

FIG. 3 is one example of the non-volatile data holding circuit which is comprised of ferroelectric memories. The non-volatile I/F 107 has two (for inputting and for outputting) or one (either for inputting or for outputting) non-volatile data holding circuit(s) for each bit of the data bus 106. The non-volatile data holding circuit in FIG. 3 is a example of a non-volatile data holding circuit for outputting data, and an input terminal DIN is connected with the functional block, and an output terminal DOUT is connected with the data bus. On the contrary, in a non-volatile data holding circuit for inputting data, the input terminal DIN is connected with the data bus, and the output terminal DOUT is connected with the functional block.

In FIG. 3, a first inverter circuit 201A and a second inverter circuit 201B form the data hold circuit (hereafter, referred to as latch circuit) 202. A signal which is inputted in an output control terminal 202C of the second inverter circuit 201B is an opposite phase signal of a CLK. Therefore, the latch circuit inputs data from the input terminal DIN and outputs inverted data during the CLK is high (value is “1”), and holds the input data during the CLK is low (value is “0”).

A first ferroelectric capacitor 203A and a second ferroelectric capacitor 203B are connected to a data line 202B (intermediate node 203E) of the latch circuit. In the first ferroelectric capacitor 203A and the second ferroelectric capacitor 203B, respective electrodes on opposite side of the data line 202B are connected with a first drive circuit 204A and a second drive circuit 204B via a first plate line 203C and a second plate line 203D, respectively. The first ferroelectric capacitor 203A and the second ferroelectric capacitor 203B (hereafter, referred to as non-volatile memories), are non-volatile memory devices for holding data which is held in the latch circuit.

When the system LSI is running, a register (set of the above latch circuits) in the non-volatile data holding units of each logic circuit block holds data inputted from the outside and data to be sent from the inside. However, this register is usually volatile, so that the data is lost when the system LSI is powered off. In order to prevent the data loss, the non-volatile data holding circuit in FIG. 3 enables to store the data stored in the register into the non-volatile memory, so that it is possible to reproduce, on start-up, the data in the register which has existed prior to the power-off. More specifically, when the system LSI is powered off, data in the latch circuit in the I/F is stored into a non-volatile memory, and when the system LSI is powered on again, the data is read out from the non-volatile memory to be stored into the latch circuit in the I/F, so that it is possible to restore the data which has existed prior to the power-off, which makes it possible to restart the system LSI at a high speed. Thereby, even if inside of the logic circuit block is initialized, the non-volatile I/F 107 holds data when the system LSI is powered off, so that the system can reproduce an operation which has been performed prior to the power-off.

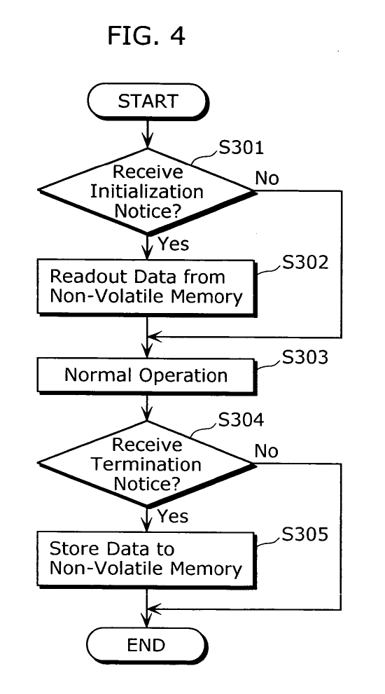

FIG. 4 is a flowchart showing processing performed by each of functional blocks (non-volatile logic circuits) 101 to 104 in FIG. 2 when the system LSI is power on and when the system LSI is powered off.

When the system LSI is powered on, each functional block determines whether or not an initialization notice is received at Step S301, and if the initialization notice is received, then in each non-volatile data holding circuit in the non-volatile I/F 107, data stored in a non-volatile memory is read out to be held in the latch circuit at Step S302, and the processing proceeds usual operations at Step S303. Here, the data is read out from the non-volatile memory under control of a first drive circuit 204A and a second drive circuit 204B shown in FIG. 3. Next, when the system LSI is powered off, each functional block determines whether or not a terminal notice is received at Step S304, and if the terminal notice is received, then in each non-volatile data holding circuit in the non-volatile I/F 107, the data stored in the latch circuit is stored into the non-volatile memory. Here, the data is stored into the non-volatile memory under control of the first drive circuit 204A and the second drive circuit 204B.

Moreover, if the non-volatile memory is a ferroelectric memory, the below-described effect can be achieved. The ferroelectric memory can be easily integrated in a CMOS circuit, thereby easily forming the ferroelectric memory in the CMOS circuit, so that the ferroelectric memory can be arranged near a logic circuit, such as a microcomputer. Thereby, it is possible to shorten a data line which connects the data hold unit in the logic circuit with the non-volatile memory, so that data can be written and read out at a high speed.

(First Variation)

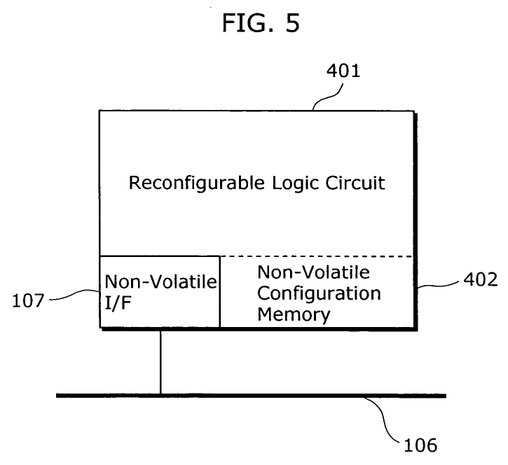

Furthermore, the functional block in FIG. 2 can have a structure shown in FIG. 5.

The functional block which is a non-volatile logic circuit shown in FIG. 5 is comprised of: a non-volatile data holding circuit 107 which includes a ferroelectric capacitor in an input/output unit (non-volatile I/F 107) of a functional block 401 having a reconfigurable logic circuit; and a non-volatile configuration memory 402 which includes a ferroelectric capacitor for storing configuration data used to program the reconfigurable logic circuit.

Thereby, it is possible to form a memory for storing the configuration data and resume data (input/output data) by using single-memory forming processing.

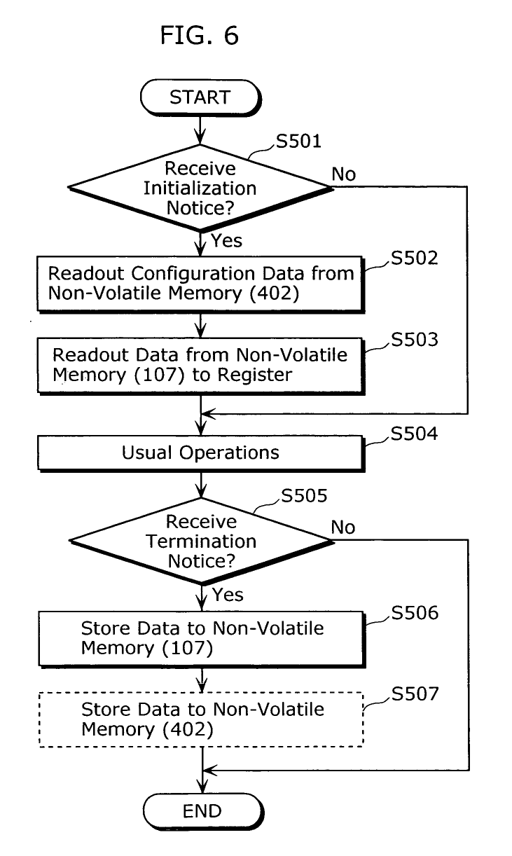

FIG. 6 is a flowchart showing processing performed by the non-volatile logic circuit shown in FIG. 5 when the system LSI is power on and when the system LSI is powered off.

When the system LSI is powered on, the functional block 401 determines whether or not an initialization notice is received at Step S501, and if the initialization notice is received, then data stored in the ferroelectric capacitor for storing configuration data is read out in order to program the reconfigurable logic circuit at Step S502, then data stored in the non-volatile memory in the non-volatile data holding circuit in the I/F is read out to be held in the register (latch circuits) at Step S503, and the processing proceeds usual operations at Step S504. Next, when the system LSI is powered off, the functional block 401 determines whether or not a terminal notice is received at Step S505, and if the terminal notice is received, then data stored in the register (latch circuits) in the I/F is stored into the non-volatile memory in the non-volatile data holding circuit. Note that, in a case that the configuration data is changed, the configuration data is stored in the ferroelectric capacitor for storing configuration data at Step S507.

(Second Variation)

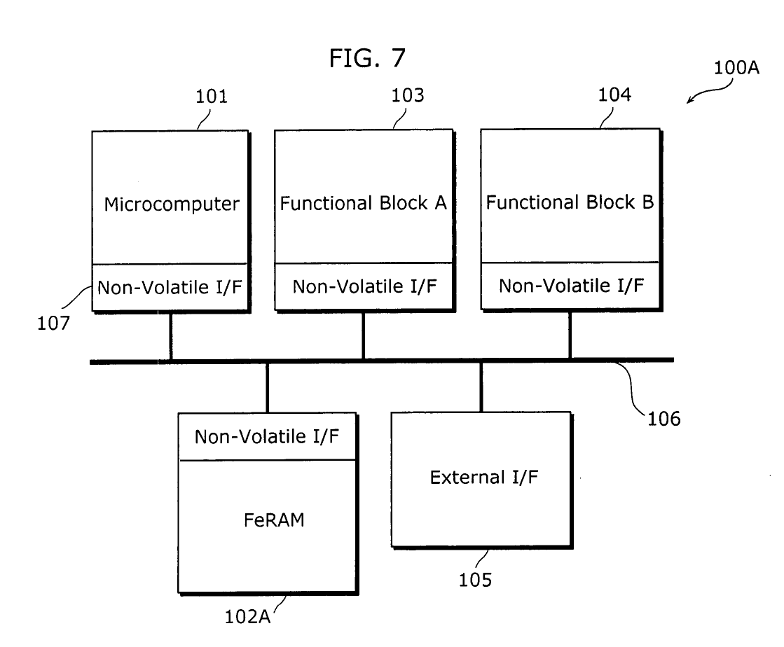

Still further, the functional block 102 with a function as a memory device in FIG. 2 can be a functional block 102A having a ferroelectric memory (FeRAM) to form a system LSI 100A, as shown in FIG. 7.

As shown in FIG. 7, the ferroelectric memory is integrated with other functions on a single chip, thereby unifying the memory functions into to the ferroelectric memory, so that the memory forming processing can be simplified.

(Third Variation)

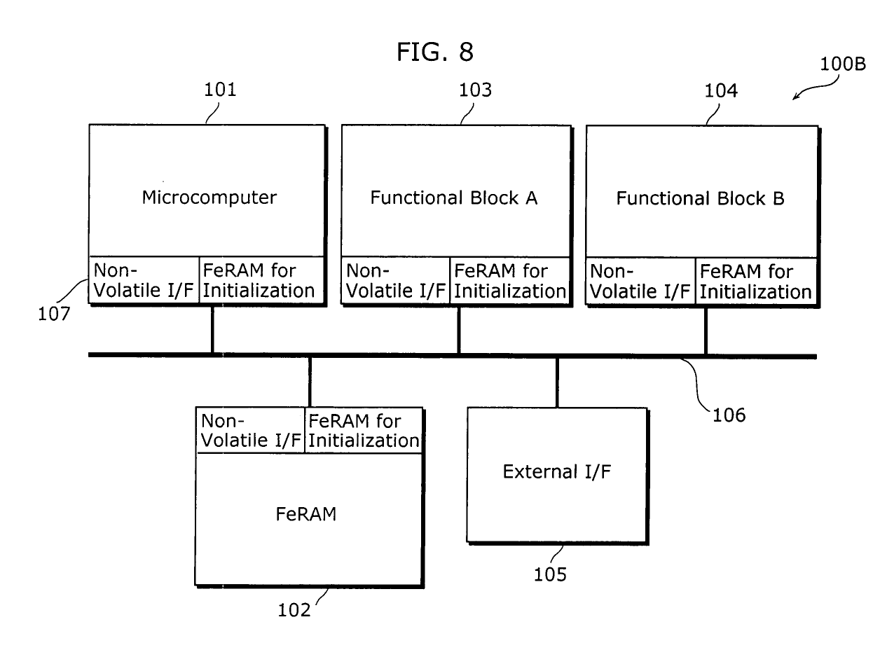

Still further, as shown in FIG. 8, a ferroelectric memory 701 which is used for initialization is formed in the logic circuit of each functional block, in order to store initialization data for each functional block.

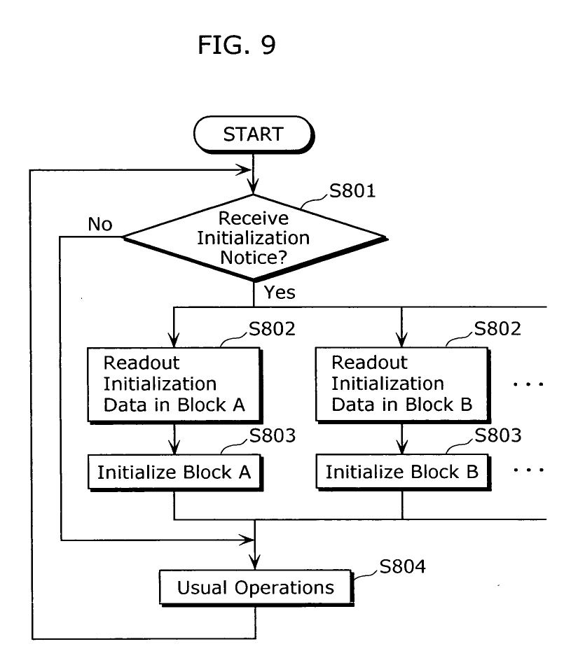

FIG. 9 is a flowchart showing initialization processing performed by a system LSI 100B in FIG. 8 when the system LSI is powered on. When the system LSI is powered on, the system LSI 100B determines whether or not an initialization notice is received at Step S801, and if the initialization notice is received, then data for initialization is read out from the ferroelectric memory which is used for initialization of every functional blocks at Step S802, then the functional blocks are simultaneously initialized at Step S803, and the processing proceeds usual operations at Step S804.

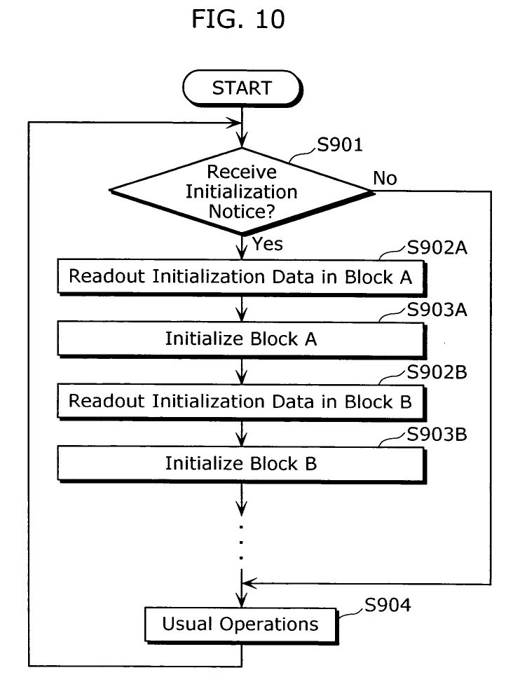

On the other hand, FIG. 10 is a flowchart showing initialization processing performed by the conventional system SLI when the system SLI is powered on. When the system LSI is powered on, the conventional system LSI determines whether or not an initialization notice is received at Step S901, and if the initialization notice is received, data for initialization is read out from a ferroelectric memory which is used for initialization of a functional block A at Step S902A, and then the functional block A is initialized. Subsequently, another data for initialization is read out from the ferroelectric memory which is used for initialization of a functional block B at Step S902B, and then the functional block B is initialized. After repeating the above steps for all functional blocks, the processing proceeds usual operations at Step S904.

While a plurality of functional blocks have conventionally been initialized one by one, the structure of FIG. 8 enables a plurality of the functional blocks to be initialized simultaneously, so that a time period required for the initialization can be shortened.

Note that the present embodiment has described the non-volatile memory in the non-volatile data holding circuit as the ferroelectric memory, but the non-volatile memory may be other non-volatile memories, such as an EEPROM and a MRAM.

According to the present invention, the logic circuit having the non-volatile interface has effects of implementing resume operation for restoring data which has existed prior to power-off, of shortening a time period required to initialize the system, and the like, and the logic circuit is useful to form a system LSI.

Although the present invention has been fully described by way of examples with reference to the accompanying drawings, it is to be noted that various changes and modifications will be apparent to those skilled in the art. Therefore, unless otherwise such changes and modifications depart from the scope of the present invention, they should be construed as being included therein.

What is claimed is:

1. A non-volatile logic circuit comprising:
a logic circuit block; and
an input/output unit operable to input and output data between said logic circuit block and a data bus,
wherein said input/output unit has a non-volatile data holding circuit which holds the data.

2. The non-volatile logic circuit according to claim 1,
wherein said non-volatile data holding circuit has a ferroelectric capacitor.

3. The non-volatile logic circuit according to claim 2,
wherein said logic circuit block is a reconfigurable circuit which is programmed according to configuration data, and has a ferroelectric capacitor for storing the configuration data.

4. The non-volatile logic circuit according to claim 2,
wherein said non-volatile logic circuit further has a ferroelectric memory core.

5. The non-volatile logic circuit according to claim 4,
wherein said ferroelectric memory core is operable to store data for initialization of said logic circuit block.

6. The non-volatile logic circuit according to claim 1,
wherein said non-volatile data holding circuit is further operable to hold configuration data for said logic circuit block.

7. A system large-scale integration (LSI) comprising
a plurality of non-volatile logic circuits which are connected to a data bus,
wherein said non-volatile logic circuit has:
a logic circuit block; and
an input/output unit operable to input and output data between said logic circuit block and a data bus,
wherein said input/output unit has a non-volatile data holding circuit which holds the data.
